(19) United States
(12) Patent Application Publication
(10) Pub. No.: US 2013/0175726 A1
(43) Pub. Date: Jul. 11, 2013

(54) METHOD FOR MANUFACTURING SILICON WAFER

(71) Applicant: GlobalWafers Japan Co., Ltd., Kitakanbara-gun (JP)

(72) Inventors: Toshiro MINAMI, Hadano-shi (JP); Kazuhiko Kashima, Hadano-shi (JP); Mitsuo Higasa, Hadano-shi (JP); Susumu Maeda, Hadano-shi (JP)

(73) Assignee: GlobalWafers Japan Co., Ltd., Kitakanbara-gun (JP)

(21) Appl. No.: 13/734,076

(22) Filed: Jan. 4, 2013

(30) Foreign Application Priority Data
Jan. 10, 2012 (JP) 2012-002564
Jan. 18, 2012 (JP) 2012-007992

(51) Int. Cl. C30B 15/04

(52) U.S. Cl. CPC C30B 15/04
USPC 264/81

(57) ABSTRACT

A method for manufacturing a silicon wafer is provided in which a low-temperature thermal process for growing a thermal donor to be a precipitate nucleus of BMD is not needed, a defect-free layer is formed in a surface layer portion even in a short thermal processing time, a BMD density is increased in a bulk portion. A silicon single crystal having a predetermined oxygen concentration and a predetermined nitrogen concentration is grown by Czochralski method in which nitrogen is added in an inert gas atmosphere containing hydrogen gas, by controlling V/G to form a region where a vacancy-type point defect exists, a silicon wafer sliced from the silicon single crystal is subjected to a planarization process and a mirror polish process, and this wafer is subjected to an RTP in an oxidizing gas atmosphere at a maximum achievable temperature from 1250° C. to 1380° C. for 1 second to 60 seconds.

### BACKGROUND OF THE INVENTION

1. Field of the Invention

The present invention relates to a method for manufacturing a silicon wafer where a silicon single crystal is grown by a Czochralski method (hereinafter referred to as CZ method) in which nitrogen is added to a silicon melt in an inert gas atmosphere to which hydrogen gas is added, and a silicon wafer is obtained by slicing the silicon single crystal and heat-treated.

2. Description of the Related Art

As for the silicon wafer (hereinafter simply referred to as wafer) used as a substrate for forming a semiconductor device, it is required that grown-in defects, such as COP (Crystal Originated Particle), do not exist in a surface layer portion of the wafer to be a device active region (particularly, region from its surface to a depth of 2 μm to 5 μm). In addition, in order to raise gettering capability for metal impurities incorporated during a semiconductor device process, it is required that a BMD (Bulk Micro Defect) density should be increased in the bulk portion which is an inner layer of the surface layer portion of the wafer.

The following methods are known as a method for manufacturing the silicon wafer in which such a grown-in defect does not exist. For example, Japanese Patent Application Laid-Open (kokai) No. H8-330316 (Patent Literature 1) discloses a technology for growing a silicon single crystal, controlling V/G (V indicates a pull rate and G indicates a temperature gradient in the direction of a raising axis of the silicon single crystal) by the CZ method in order to form a defect-free region.

Further, for example, Japanese Patent Application Laid-Open (kokai) No. 2006-261632 (Patent Literature 2) discloses a technology in which the wafer is heat treated for 1 hour or longer in the inert gas or reduction gas atmosphere at a high temperature of 1250° C. or higher, so that a grown-in defect is eliminated in the surface layer portion of the wafer, and BMD is precipitated in the bulk portion.

However, for growing a defect-free region as in Patent Literature 1, Ni (Pi) areas with few precipitate nuclei of BMD and Nv (Pv) areas with many precipitate nuclei tend to be intermingled. Thus, it is difficult to increase the precipitate nuclei of BMD all over the wafer.

Further, since the thermal process takes a long time in the technology like Patent Literature 2, productivity is reduced and a slip tends to take place in the wafer. Furthermore, since oxygen in the surface layer portion of the wafer out-diffuses, an oxygen concentration in the surface layer portion decreases. Therefore, in the case where such a wafer is used in a semiconductor device process, a dislocation generated by application of stress or distortion produced during the process is likely to elongate. Accordingly, a yield in a semiconductor device is reduced.

Then, WO 2007/013189 (Patent Literature 3) discloses a technology for forming the small-sized oxygen precipitate nuclei with a high density in the bulk of the wafer. According to this, the silicon single crystal is grown by the CZ method in the inert gas atmosphere containing a substance including a hydrogen atom, so that thermal donors (TD) are formed in a bulk crystal at a high density in the state of as-grown. Further, it is attained by heat-treatment at a low temperature (400° C. to 650° C.) before the thermal donors disappear due to high temperature annealing (heat treatment in a non-oxidizing atmosphere (Ar/H₂) at 1000° C. to 1300° C. (inclusive)).

Furthermore, National Publication of Translated Version (kohyo) No. 2001-509319 (Patent Literature 4) discloses a technology in which a silicon wafer is subjected to a rapid thermal process in the order of seconds at a high temperature of 1150° C. or higher to form a defect-free layer in the surface layer portion of the wafer.

Still further, Japanese Patent Application Laid-Open (kokai) No. 2006-312575 (Patent Literature 5) discloses a technology which allows both formation of a surface-activated defect-free region and generation of BMD in the wafer. In growing the silicon single crystal by the CZ method, a hydrogen partial pressure in an inactive atmosphere in a growing apparatus is set to 40 Pa to 400 Pa (inclusive) to grow a single crystal straight cylindrical portion as a defect-free region where a grown-in defect does not exist. It is attained by subjecting the wafer having a P_{I} area all over the wafer surface and a high oxygen concentration to the rapid thermal annealing process.

However, the technology described in Patent Literature 3, addition of the substance including hydrogen atom allows a thermal donor concentration to be high, but the above-mentioned low-temperature thermal process for growing up the thermal donor into the precipitate nucleus of BMD is needed in order to finally increase the BMD density. Therefore, with this technology, a number of processes increases and there is a problem that productivity is reduced.

Further, the technology described in Patent Literature 4 does not aim to increase the BMD density and thermal processing time is short. Therefore, there is a limit to increasing the BMD density of the bulk portion only by this thermal process.

Furthermore, in the technology described in Patent Literature 5, since the silicon single crystal of the defect-free region is grown by controlling V/G, it is necessary to control V (pull rate) to be low. Thus, there is a problem that productivity may be reduced.

### SUMMARY OF THE INVENTION

The present invention arises in view of the above-mentioned background. The present invention does not need the low-temperature thermal process for growing up a thermal donor into a precipitate nucleus of BMD, thermal processing time is short, and it is possible to form a defect-free layer in a surface layer portion and increase a BMD density in a bulk portion. Furthermore, the present invention aims to prevent an oxygen concentration of the surface layer portion of a wafer from decreasing and offer a method for manufacturing a silicon wafer with high productivity.

According to a first aspect of the present invention, there is provided a method for manufacturing a silicon wafer, the method comprising the steps of growing a silicon single crystal having an oxygen concentration of from 1.0×10¹⁸ to 1.8×10¹⁸ atoms/cm³ and a nitrogen concentration of 2.8×10¹⁴ to 5.0×10¹⁵ atoms/cm³ by the Czochralski method in which nitrogen is added to a silicon melt in an inert gas atmosphere to which hydrogen gas is added, by controlling V/G (where V indicates a pull rate and G indicates a temperature gradient in the direction of a raising axis of the silicon single crystal) so as to form a region where a vacancy-type point defect exists; slicing a silicon wafer from the above-mentioned grown silicon single crystal, the silicon wafer then being subjected to a planarization process and a mirror polish process; and subjecting the above-mentioned mirror polished silicon wafer to a rapid thermal process in an oxidizing gas atmosphere at a maximum achievable temperature from 1250° C. to 1380° C. for 1 second to 60 seconds.

According to a second aspect of the present invention, there is provided a method for manufacturing a silicon wafer, the method comprising the steps of growing a silicon single crystal having an oxygen concentration of from 1.0×10¹⁸ to 1.8×10¹⁸ atoms/cm³ and a nitrogen concentration of 2.8×10¹⁴ to 5.0×10¹⁵ atoms/cm³ by the Czochralski method in which nitrogen is added to a silicon melt in an inert gas atmosphere to which hydrogen gas is added, by controlling V/G (where V indicates a pull rate and G indicates a temperature gradient in the direction of a raising axis of the silicon single crystal) so as to form a region where a vacancy-type point defect exists; slicing a silicon wafer from the above-mentioned grown silicon single crystal, the silicon wafer then being subjected to a planarization process and a mirror polish process; subjecting the above-mentioned mirror polished silicon wafer to a first rapid thermal process in an inert gas atmosphere at a maximum achievable temperature from 1250° C. to 1380° C. for 1 second to 60 seconds; and after the above-mentioned first rapid thermal process, subjecting the above-mentioned silicon wafer to a second rapid thermal process in an oxidizing gas atmosphere at a maximum achievable temperature from 1250° C. to 1380° C. for 1 second to 60 seconds.

It is preferable that the partial pressure of hydrogen gas contained in the above-mentioned inert gas atmosphere to which hydrogen gas is added is 3% or less.

According to the present invention, there is provided a method for manufacturing a silicon wafer, the method not needing the low-temperature thermal process for growing up a thermal donor into a precipitate nucleus of BMD, allowing thermal processing time to be short, a defect-free layer to be formed in a surface layer portion, and a BMD density in a bulk portion to be increased, preventing an oxygen concentration of the surface layer portion of a wafer from decreasing, and allowing high productivity.

### BRIEF DESCRIPTION OF THE DRAWING

FIG. 1 is a schematic sectional view showing an example of a silicon single crystal growing apparatus used in a step of growing the silicon single crystal in a method for manufacturing a silicon wafer in accordance with the present invention.

FIG. 2 is a graph showing an example of a thermal process sequence of RTP in the case of performing a first RTP followed by a second RTP.

### DESCRIPTION OF THE PREFERRED EMBODIMENTS

Hereinafter, the preferred embodiments of the present invention will be described in detail with reference to the drawings etc.

In a first aspect of a method for manufacturing a silicon wafer in accordance with the present invention, there is provided a step of growing a silicon single crystal having an oxygen concentration of from 1.0×10¹⁸ to 1.8×10¹⁸ atoms/cm³ and a nitrogen concentration of 2.8×10¹⁴ to 5.0×10¹⁵ atoms/cm³ by the Czochralski method in which nitrogen is added to a silicon melt in an inert gas atmosphere to which hydrogen gas is added, by controlling V/G (where V indicates a pull rate and G indicates a temperature gradient in the direction of a raising axis of the silicon single crystal) so as to form a region where a vacancy-type point defect exists. There is further provided a step of slicing a silicon wafer from the above-mentioned grown silicon single crystal, the silicon wafer then being subjected to a planarization process and a mirror polish process. Furthermore, there is provided a step of subjecting the above-mentioned mirror polished silicon wafer to a rapid thermal process in an oxidizing gas atmosphere at a maximum achievable temperature from 1250° C. to 1380° C. for 1 second to 60 seconds (hereinafter, may be simply referred to as RTP (Rapid Thermal Process)).

Thus, according to the present invention, when growing the silicon single crystal, V/G is controlled so as to form the region where the vacancy-type point defect exists, to thereby increase the pull rate (V) compared with the case where a defect-free region is formed.

Furthermore, since the silicon single crystal is grown in the inert gas atmosphere to which hydrogen gas is added, the precipitate nuclei of BMD can be increased in the silicon single crystal, and a BMD density can be increased at a later RTP.

Further, since nitrogen is added to the silicon melt to grow the silicon single crystal, even when the region where the vacancy-type point defect exists is formed, a size of COP contained in the region can be reduced. Therefore, COP in the surface layer portion of the wafer can be eliminated in a later RTP.

It is to be noted that a method of adding nitrogen to the silicon melt can be performed such that when polycrystalline silicon is filled into a silica glass crucible before starting to grow the silicon single crystal, a method for simultaneously filling wafer pieces coated with nitride film is carried out, for example. Alternatively, it can be carried out by well-known methods, such as a method of adding nitrogen gas simultaneously with hydrogen gas to the above-mentioned inert gas atmosphere.

In addition, the oxygen concentration of the silicon single crystal to be grown is set as 1.0×10¹⁸ to 1.8×10¹⁸ atoms/cm³ and the nitrogen concentration is set as 2.8×10¹⁴ to 5.0×10¹⁵ atoms/cm³, so that the precipitate nuclei of BMD increased in the bulk portion of the wafer as described above can be precipitated as BMD, without eliminating them at a later RTP

Therefore, it is not necessary to perform a low-temperature thermal process in order to cause the thermal donor as described above to grow into the precipitate nucleus of BMD. It is to be noted that a method of adjusting the above-mentioned oxygen concentration can be performed by the well-known methods, such as for example adjusting a number of rotations of the silica glass crucible or internal furnace pressure when growing the silicon single crystal.

Furthermore, since RTP is performed in an oxidizing gas atmosphere, it is possible to prevent out-diffusing of oxygen from the surface layer portion rather than performing RTP only in an inert gas atmosphere (for example, Ar 100%). Therefore, it is possible to prevent the reduction in pinning effect of slip dislocation caused by reduction in oxygen concentration.

It is to be noted that “oxidizing gas atmosphere” as used herein includes not only a 100% oxygen gas atmosphere but also a mixed gas atmosphere having an oxygen partial pressure of from 20% to 100% (except 100%) in an inert gas atmosphere (preferably argon gas atmosphere).

Further, since the above-mentioned RTP is carried out at the maximum achievable temperature of 1250° C. to 1380° C., it is easy to dissolve an inner-wall oxide film of COP which exists in the surface layer portion. In addition, since it is carried out in an oxidizing gas atmosphere, a greater quantity of interstitial silicon can be introduced into the above-mentioned surface layer portion than in the inert gas atmosphere. Therefore, even if thermal processing time is short (1 second to 60 seconds), COP in the surface layer portion can be eliminated.

In the case where the above-mentioned oxygen concentration is less than 1.0×10¹⁸ atoms/cm³, or in the case where the above-mentioned oxygen concentration is 1.0×10¹⁸ atoms/cm³ or more and a nitrogen concentration is less than 2.8×10¹⁴ atoms/cm³, the precipitate nucleus of the generated BMD as described above is likely to disappear in a later RTP, this is not preferred. Since the oxygen concentration of the surface layer portion is high in the case where the above-mentioned oxygen concentration exceeds 1.8×10¹⁸ atoms/cm³, the inner-wall oxide film of COP which exists in the surface layer portion may be hard to dissolve in a later RTP. Further, since it is impossible to fill the inside of COP even if a large quantity of interstitial silicon is introduced, COP may remain in the surface layer portion. In the case where the above-mentioned nitrogen concentration exceeds 5×10¹⁵ atoms/cm³, since nitrogen precipitation takes place in the silicon melt when growing the silicon single crystal, it is difficult to obtain a crystal of non-dislocation.

In the case where the maximum achievable temperature in the above-mentioned RTP is less than 1250° C., since the inner-wall oxide film of COP which exists in the surface layer portion is hard to dissolve, it may be difficult to eliminate COP in the surface layer portion. In the case where the above-mentioned maximum achievable temperature exceeds 1380° C., the high temperature raises the possibility that slip dislocation may take place in the wafer, this may be undesirable in terms of the lifetime of an RTP apparatus to be used.

In the case where the holding time of the maximum achievable temperature in the above-mentioned RTP is less than 1 second, it may be difficult for the short thermal process time to sufficiently eliminate COP in the surface layer portion and precipitate BMD in the bulk portion. In the case where the above-mentioned holding time exceeds 60 seconds, productivity may be reduced.

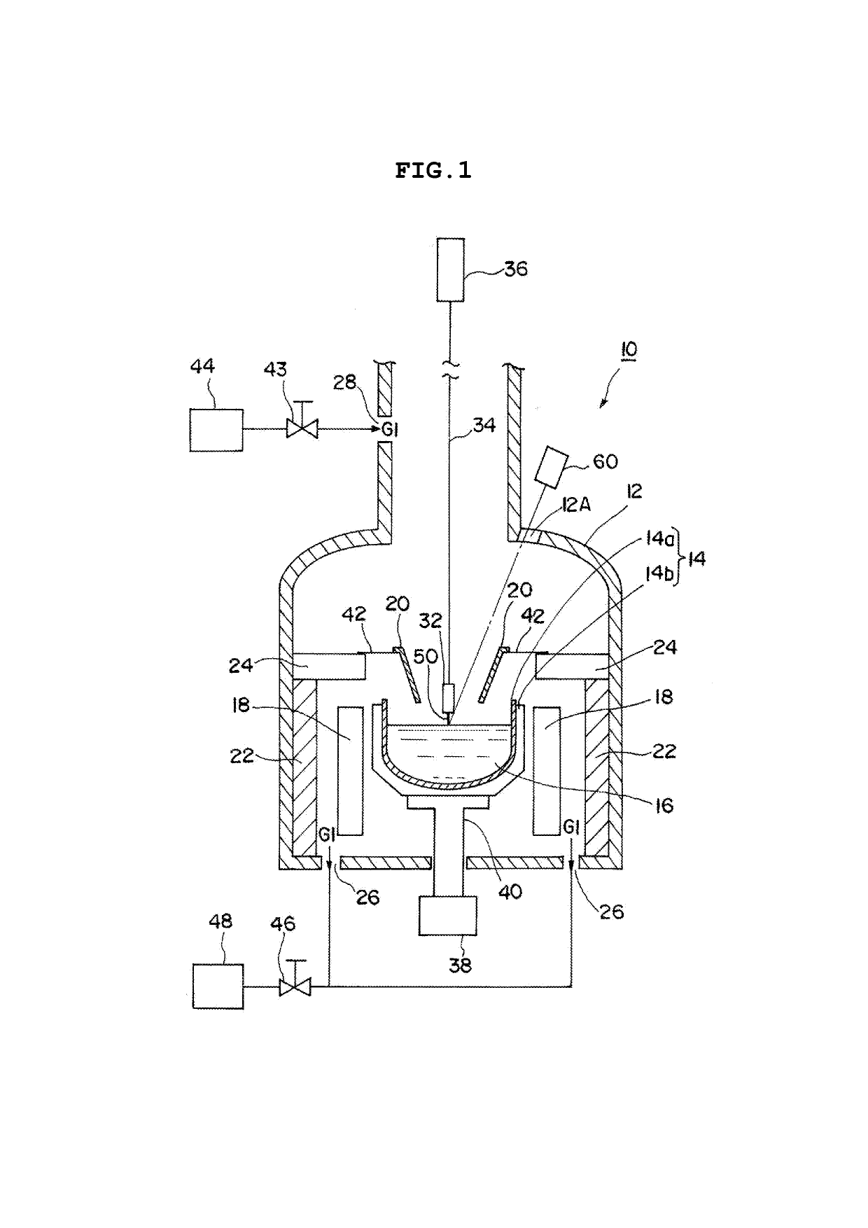

FIG. 1 is a schematic sectional view showing an example of the silicon single crystal growing apparatus used in the step of growing the silicon single crystal in the method for manufacturing the silicon wafer in accordance with the present invention.

In the method for manufacturing the silicon wafer in accordance with the present invention, the silicon single crystal growing apparatus 10 used in the step of growing the silicon single crystal is provided with, as shown in FIG. 1, a furnace 12, a crucible 14 which is disposed in the furnace 12 and holds silicon materials (mainly polysilicon), and a heater 18 which is disposed in the perimeter of the crucible 14, heats the crucible 14, and melts the silicon materials held in the crucible 14 to provide a silicon melt 16. It is further provided with a cylindrical heat shield 20 which is disposed above the silicon melt 16 and shields radiant heat incident to the silicon single crystal (not shown) pulled up from the silicon melt 16 by the CZ method.

The crucible 14 is provided with a silica glass crucible 14a for holding the silicon melt 16 and a carbon crucible 14b which accommodates the silica glass crucible 14a.

A first insulating member 22 is provided in the perimeter of the heater 18. A second insulating member 24 is provided on the first insulating member 22 at a predetermined distance away from the heater 18.

Above the heat shield 20, a carrier gas feed opening 28 is provided for supplying carrier gas (inert gas atmosphere to which hydrogen gas is added) G1 passing through an inner circumference of the heat shield 20, passing between the heat shield 20 and the silicon melt 16, and discharged out of the furnace 12 through an outlet 26 located under the crucible 14.

A pull-up wire 34 to which a seed chuck 32 for holding a seed crystal 50 used for growing the silicon single crystal (not shown) is attached is provided above the crucible 14. The pull-up wire 34 is attached to a wire rotation lift mechanism 36 which is rotatable and liftable, and provided outside the furnace 12.

The crucible 14 is attached to a crucible rotating shaft 40 which passes through the bottom of the furnace 12 and can be rotated and lifted by a crucible rotation lift mechanism 38 provided outside the furnace 12.

The heat shield 20 is held above the crucible 14 by means of a heat shield supporting member 42 attached to an upper surface of the second insulating member 24.

A carrier gas feed unit 44 for supplying the carrier gas G1 into the furnace 12 is connected to the carrier gas feed opening 28 through a massflow controller 43. A carrier gas discharge unit 48 for discharging the carrier gas G1 passing through the inner circumference of the heat shield 20 and passing between the heat shield 20 and the silicon melt 16 is connected to the outlet 26 through a butterfly valve 46. An amount of the carrier gas G1 supplied into the furnace 12 is controlled by adjusting the massflow controller 43, and an amount of exhaust gases (including the carrier gas G1 and SiOₓ gas generated from the silicon melt 16) exhausted from the furnace 12 is controlled by adjusting the butterfly valve 46.

Further, it is possible to observe how the silicon single crystal is grown and measure a surface temperature of the silicon melt 16 etc., by means of an imaging device 60 (CCD camera) through a monitoring window 12A provided for the furnace 12.

The method of slicing the above-mentioned grown silicon single crystal to provide the silicon wafer is performed by the well-known method using a wire saw or a concave blade.

The above-mentioned planarization process is performed by the well-known methods, such as for example, a lapping process of lapping both sides of the silicon wafer obtained by slicing the above-mentioned silicon single crystal using loose abrasive grains, a grinding process of grinding the one side or both the sides using a diamond whetstone in which diamond grains are electrodeposited, a chemical polishing process of chemically polishing substantially both the sides using a mixed solution of hydrogen fluoride, nitric acid, and acetic acid, a solution of sodium hydroxide, or a solution of potassium hydroxide.

The above-mentioned mirror polish process is carried out by the well-known method in which one side the wafer where semiconductor devices are to be formed or both sides of the wafer is pressed onto a polishing cloth and an abrasive agent is supplied while rotating the wafer in a sheet-fed mode or a batch mode.

It is to be noted that by RTP in the present invention is meant, for example, a thermal process using a well-known RTP apparatus shown in FIG. 1 of Japanese Patent Application Laid-Open (kokai) No. 2011-233556. In this thermal process, the silicon wafer subjected to the above-mentioned mirror polish process is placed in a reaction tube kept at a predetermined treatment temperature (for example, 400° C. to 600° C.). Subsequently, the temperature is rapidly increased to the above-mentioned maximum achievable temperature at a temperature rump up rate of 1° C./second or more, and the above-mentioned maximum achievable temperature is held for from 1 second to 60 seconds (inclusive), then the temperature is rapidly decreased to the above-mentioned predetermined treatment temperature at a temperature ramp down rate of 1° C./second or more.

It is preferable that the above-mentioned temperature ramp up rate and temperature ramp down rate are from 5° C./second to 200° C./second.

By employing such rates, it is possible to raise the productivity and prevent a slip from generating due to the rapid temperature changes at the time of increasing and decreasing the temperature.

More preferably, the above-mentioned temperature ramp up rate and temperature ramp down rate are from 10° C./second to 150° C./second.

It is preferable that a partial pressure of hydrogen gas contained in the above-mentioned inert gas atmosphere to which hydrogen gas is added is 3% or less.

By employing such a hydrogen gas partial pressure, rapid hydrogen addition to the silicon single crystal can be controlled, so that a hydrogen defect may be prevented from generating in the silicon single crystal.

More preferably, the maximum achievable temperature in the above-mentioned RTP is from 1250° C. to 1300° C.

The higher the above-mentioned maximum achievable temperature, the more likely the precipitate nucleus of BMD generated when growing the silicon single crystal is to disappear without becoming BMD. Therefore, a BMD density can be further raised by employing such a temperature range.

It is to be noted that, when growing the silicon single crystal by the CZ method, a size of COP generated in the region where the vacancy-type point defect of the silicon single crystal to be grown exists may be large because of variations (changes) in the growing environments (heater output, pull rate, etc.). If this is the case, it may be difficult to eliminate COP in the surface layer portion only by RTP in the above-mentioned oxidizing gas atmosphere.

In this case, it is preferable that further RTP in the inert gas atmosphere is added before RTP in the above-mentioned oxidizing gas atmosphere.

That is, a second aspect in the method for manufacturing the silicon wafer of the present invention, there is provided a step of growing a silicon single crystal having an oxygen concentration of from 1.0×10¹⁸ to 1.8×10¹⁸ atoms/cm³ and a nitrogen concentration of 2.8×10¹⁴ to 5.0×10¹⁵ atoms/cm³ by the Czochralski method in which nitrogen is added to a silicon melt in an inert gas atmosphere to which hydrogen gas is added, by controlling V/G (where V indicates a pull rate and G indicates a temperature gradient in the direction of a raising axis of the silicon single crystal) so as to form a region where a vacancy-type point defect exists (hereinafter referred to as first step). There is further provided a step of slicing a silicon wafer from the above-mentioned grown silicon single crystal, the silicon wafer then being subjected to a planarization process and a mirror polish process (hereinafter referred to as second step). Furthermore, there are provided steps of subjecting the above-mentioned mirror polished silicon wafer to a first rapid thermal process in an inert gas atmosphere at a maximum achievable temperature from 1250° C. to 1380° C. for 1 second to 60 seconds (hereinafter referred to as third step); and after the above-mentioned first rapid thermal process, subjecting the above-mentioned silicon wafer to a second rapid thermal process in an oxidizing gas atmosphere at a maximum achievable temperature from 1250° C. to 1380° C. for 1 second to 60 seconds (hereinafter referred to as fourth step).

It is to be noted that the above-mentioned first step, second step, and fourth step are similar to those described above, and the description of these steps will not be repeated herein.

As described above, even if the size of COP generated in the region where the vacancy-type point defect of the silicon single crystal exists is large because of the variations in the growing environments when growing the silicon single crystal by the CZ method, it is possible to dissolve the inner-wall oxide film of COP and reduce the COP size by performing the above-mentioned third step. Therefore, a defect-free layer can be formed more reliably in the surface layer portion. Further, since thermal processing time of the above-mentioned third step is short (1 second to 60 seconds), it is possible to minimize the productivity reduction due to the addition of this step.

It is to be noted that the above-mentioned third step is performed in the inert gas atmosphere, so that oxygen in the surface layer portion may out-diffuse to decrease the oxygen concentration of the above-mentioned surface layer portion. However, in the later fourth step, since oxygen can be in-diffused into the above-mentioned surface layer portion, the oxygen concentration decreased at the above-mentioned third step can be compensated at the above-mentioned fourth step. Therefore, it is possible to prevent the oxygen concentration of the surface layer portion of the wafer from decreasing.

It is preferable that a first RTP in the above-mentioned third step is carried out in then inert gas atmosphere.

In the case where the above-mentioned first RTP is in the nitrogen gas atmosphere, a nitride film is formed on the surface of the wafer in the RTP. However, an etching process etc. must be newly added to remove this nitride film, leading to considerable reduction in productivity, this is not preferred.

In the case where the above-mentioned first RTP is in the hydrogen gas atmosphere, the oxidizing gas is introduced at the later fourth step, so that there is a risk of explosion etc., this is not preferred.

Further, in the case where the above-mentioned first RTP is in the oxidizing gas atmosphere, the above-mentioned second RTP is performed twice substantially. In this case, since the thermal processing time in the oxidizing gas atmosphere is long, the oxygen concentration of the surface layer portion increases in the second half of the thermal process. At this stage, an inner-wall oxide film is formed in COP generated when growing the silicon single crystal and having too large a size to disappear and remain. Accordingly, even if a large quantity of interstitial silicon is introduced because of the oxidizing gas atmosphere, there is a possibility that COP may remain in the surface layer portion.

It is preferable that the above-mentioned inert gas is argon gas. By employing argon gas, it is possible to perform the above-mentioned first RTP without forming other films, such as a nitride film, or causing a chemical reaction, etc.

It is preferable that the first RTP in the above-mentioned third step is carried out at the maximum achievable temperature of 1250° C. to 1380° C.

By performing the above-mentioned first RTP at the above-mentioned maximum achievable temperature, it is easy to dissolve the inner-wall oxide film of COP existing in the surface layer portion, and COP in the surface layer portion can be reduced in size or eliminated. Therefore, even if the thermal processing time is short (1 second to 60 seconds), COP in the surface layer portion can be decreased.

In the case where the maximum achievable temperature in the above-mentioned first RTP is less than 1250° C., since the inner-wall oxide film of COP existing in the surface layer portion is hard to dissolve, it may be difficult to decrease COP in the surface layer portion. In the case where the above-mentioned maximum achievable temperature exceeds 1380° C., since the temperature rises, a possibility that slip dislocation may take place in the wafer becomes high, this is not preferred from the viewpoint of the life of the RTP apparatus to be used.

The above-mentioned first RTP and the above-mentioned second RTP may be carried out either separately or one after the other.

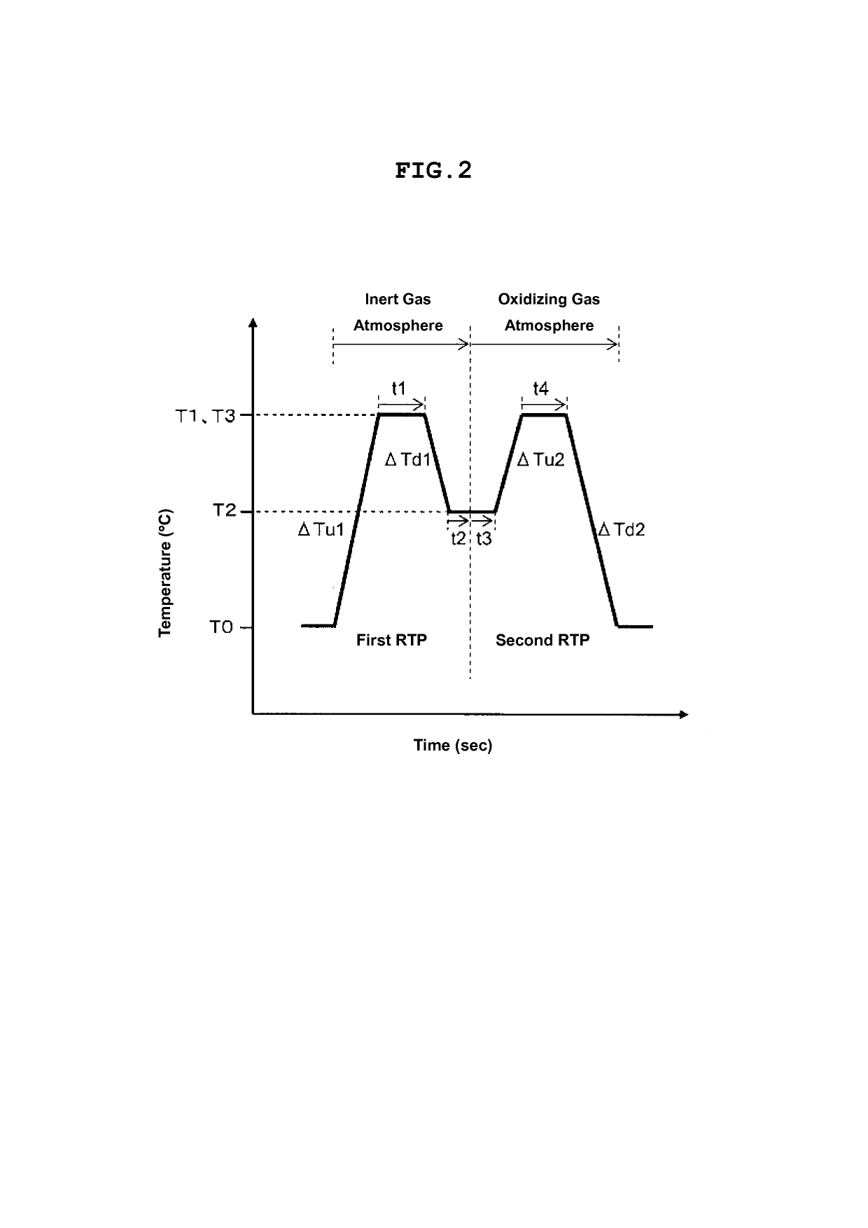

FIG. 2 is a graph showing an example of the thermal process sequence of RTP in the case of performing the first RTP followed by the second RTP.

In the case where the above-mentioned first RTP and second RTP are carried out one after the other, the above-mentioned silicon wafer subjected to the mirror polish process is placed in the reaction tube, of the well-known RTP apparatus, kept at a desired temperature T0 (for example, 400° C.) as shown in FIG. 2. Then, in the inert gas atmosphere, the temperature is rapidly increased to a first temperature (1250° C. to 1380° C.) T1 at a first temperature ramp up rate ΔTu1, and the above-mentioned first temperature T1 is held for a predetermined time (1 second to 60 seconds) t1. Subsequently, the temperature is rapidly decreased from the above-mentioned first temperature T1 to a second temperature T2 at a first temperature ramp down rate ΔTd1, and the above-mentioned second temperature T2 is held for a predetermined time t2 (the first RTP). Subsequent to this first RTP, the above-mentioned inert gas atmosphere is changed to the oxidizing gas atmosphere at the above-mentioned second temperature T2. Further, after holding the above-mentioned second temperature T2 for a predetermined time t3, the temperature is rapidly increased from the above-mentioned second temperature T2 to a third temperature (1250° C. to 1380° C.) T3 at a second temperature ramp up rate ΔTu2. Furthermore, after holding the above-mentioned third temperature T3 for a predetermined time (1 second to 60 seconds) t4, the temperature is rapidly decreased from the above-mentioned third temperature T3 to a wafer taking-out temperature (for example, T0) at a second temperature ramp down rate ΔTd2 (second RTP).

It is preferable that the above-mentioned second temperature T2 is 600° C. to 800° C.

In the case where the above-mentioned second temperature T2 is less than 600° C., the productivity as RTP may be worsened. In the case where the above-mentioned second temperature T2 exceeds 800° C., a rough surface may be generated when replacing the inert gas atmosphere with the oxidizing gas atmosphere.

It is preferable that holding times t2 and t3 to hold the above-mentioned second temperature T2 are 1 second to 30 seconds respectively. Thus, it is possible to realize RTP with high productivity. More preferably, the above-mentioned holding times t2 and t3 are 1 second to 15 seconds respectively.

It is preferable that the above-mentioned temperature ramp up rates ΔTu1 and ΔTu2 and the temperature ramp down rates ΔTd1 and ΔTd2 are 5° C./second to 200° C./second.

By employing such rates, it is possible to raise the productivity and prevent a slip from generating due to the rapid temperature changes at the time of increasing and decreasing the temperature.

More preferably, the above-mentioned temperature ramp up rates ΔTu1 and ΔTu2 and the temperature ramp down rates ΔTd1 and ΔTd2 are 10° C./second to 150° C./second.

### Example

Hereinafter, the present invention will be described in more detail with reference to Example, which should not be construed as limiting the present invention.

### [Examination 1]

Using the silicon single crystal growing apparatus 10 as shown in FIG. 1, the silica glass crucible 14a with a diameter of 32 inches was filled with silicon materials and wafer pieces coated with nitride film, which were melted by the heater 18 to provide the silicon melt 16.

Next, an inert gas atmosphere to which hydrogen gas was added to have a gas partial pressure of 3% was used as the carrier gas G1 and supplied into the furnace 12, and the seed crystal 50 was immersed in the silicon melt 16. Then, the above-mentioned seed crystal 50 was pulled up, and a neck portion with a diameter of 4 mm to 5 mm was grown to have a length of 200 mm by a dash necking process, then a larger diameter portion was grown to have a crystal diameter of as large as 310 mm. Further, a silicon single crystal having a straight cylindrical portion with a length of 1800 mm was grown, maintaining the diameter of 310 mm. At this stage, V/G (V indicates a pull rate and G indicates a temperature gradient in the direction of the raising axis of the silicon single crystal) was controlled to be at 0.20 to 0.35 mm²/(° C.·min.) so that the region where the vacancy-type point defect existed in the straight cylindrical portion might be formed, and an oxygen concentration and a nitrogen concentration at an evaluation portion were varied to grow each silicon single crystal.

The other particular manufacture conditions are as follows:
supply of carrier gas G1: 50 L/min
internal furnace pressure: 90 to 100 mbar
number of rotations of seed crystal 50: 10 rpm
number of rotations of crucible 14: 1 to 5 rpm
directions of rotation of seed crystal 50 and crucible 14: opposite directions

The resulting straight cylindrical portion of each silicon single crystal was sliced in the shape of a wafer using a wire saw. The thus obtained silicon wafers were subjected to a lapping process, a double-side grinding process, and a double-side chemical etching process by means of a mixed solution of hydrogen fluoride, nitric acid, and acetic acid. Each was further subjected to a double-side mirror polishing process to obtain a double-side polished silicon wafer with a diameter of 300 mm and a thickness of 750 μm.

Next, using the well-known RTP apparatus, the thus double-side polished silicon wafer was placed in the reaction tube kept at 400° C. Subsequently, in a 100% oxygen gas atmosphere, the temperature was rapidly increased to 1250° C. (maximum achievable temperature) at a temperature ramp up rate of 10° C./second and the above-mentioned maximum achievable temperature was held for 30 seconds. Then, the temperature was rapidly decreased to 400° C. at a temperature ramp down rate of 50° C./second. By this thermal process, an annealed wafer was produced for each of the growth conditions of the above-mentioned silicon single crystals.

As for the resulting annealed wafer, a defect density at a surface layer portion in a region from its surface to a depth of 5 μm was evaluated using an LSTD scanner MO601 manufactured by Raytex Corporation, Japan.

Further, the resulting annealed wafer was heat treated at 1000° C. for 16 hours, then a BMD density of a bulk portion (a depth of 5 μm or more) was evaluated using an IR tomography (MO-411, manufactured by Raytex Corporation, Japan).

In addition, as for the resulting annealed wafer, a slip generated at the back of the wafer was measured using an X-ray topography (XRT300, manufactured by Rigaku Corporation, Japan), to thereby evaluate the maximum length of the slip generated in the surface.

Table 1 shows experiment conditions and experiment results in Examination 1.

TABLE 1

| | | | Maximum | | | |
|---|---|---|---|---|---|---|
| | | | Achievable | Defect Density | BMD Density | |
| | Nitrogen | Oxygen | Temperature | of Surface | of | Slip |
| | Concentration | Concentration | of RTP | Layer Portion | Bulk Portion | Length |
| | (atoms/cm³) | (atoms/cm³) | (° C.) | (/cm²) | (/cm³) | (mm) |
| Comparative | 2.0 × 10¹⁴ | 0.8 × 10¹⁸ | 1250 | <1.0 | 1.0 × 10⁷ | 2 |
| Example 1 | | | | | | |
| Comparative | 2.0 × 10¹⁴ | 1.0 × 10¹⁸ | 1250 | <1.0 | 3.1 × 10⁷ | 1 |
| Example 2 | | | | | | |
| Comparative | 2.0 × 10¹⁴ | 1.2 × 10¹⁸ | 1250 | <1.0 | 1.2 × 10⁸ | 1 |
| Example 3 | | | | | | |
| Comparative | 2.0 × 10¹⁴ | 1.5 × 10¹⁸ | 1250 | <1.0 | 5.2 × 10⁸ | 1 |
| Example 4 | | | | | | |
| Comparative | 2.0 × 10¹⁴ | 1.8 × 10¹⁸ | 1250 | <1.0 | 6.0 × 10⁸ | 0 |
| Example 5 | | | | | | |
| Comparative | 2.8 × 10¹⁴ | 0.8 × 10¹⁸ | 1250 | <1.0 | 9.2 × 10⁷ | 1 |
| Example 6 | | | | | | |
| Example 1 | 2.8 × 10¹⁴ | 1.0 × 10¹⁸ | 1250 | <1.0 | 1.2 × 10⁹ | 1 |
| Example 2 | 2.8 × 10¹⁴ | 1.2 × 10¹⁸ | 1250 | <1.0 | 1.5 × 10⁹ | 1 |
| Example 3 | 2.8 × 10¹⁴ | 1.5 × 10¹⁸ | 1250 | <1.0 | 4.4 × 10⁹ | 0 |
| Example 4 | 2.8 × 10¹⁴ | 1.8 × 10¹⁸ | 1250 | <1.0 | 6.8 × 10⁹ | 0 |
| Comparative | 5.0 × 10¹⁴ | 0.8 × 10¹⁸ | 1250 | <1.0 | 7.0 × 10⁷ | 1 |
| Example 7 | | | | | | |
| Example 5 | 5.0 × 10¹⁴ | 1.0 × 10¹⁸ | 1250 | <1.0 | 3.6 × 10⁹ | 1 |
| Example 6 | 5.0 × 10¹⁴ | 1.2 × 10¹⁸ | 1250 | <1.0 | 6.0 × 10⁹ | 0 |
| Example 7 | 5.0 × 10¹⁴ | 1.5 × 10¹⁸ | 1250 | <1.0 | 5.7 × 10⁹ | 0 |
| Example 8 | 5.0 × 10¹⁴ | 1.8 × 10¹⁸ | 1250 | <1.0 | 6.5 × 10⁹ | 0 |

As shown in Table 1, in the case where the nitrogen concentration is 2.0×10¹⁴ atoms/cm³, it is considered that the BMD density is less than 1×10/cm³, even if the oxygen concentration is 1.8×10¹⁸ (Comparative Examples 1 to 5). In the case where the nitrogen concentration is 2.8×10¹⁴ atoms/cm³ or more, except for the cases (Comparative Examples 6 and 7) where the oxygen concentration is 0.8×10¹⁸ atoms/cm³, it is considered that the BMD density is 1×10⁹/cm³ or more (Examples 1 to 8). Further, it is considered that the defect density of the surface layer portion is less than 1.0/cm² in each condition and the slip length is short, causing no problem.

### [Examination 2]

The annealed wafer was produced for each condition by the same method as in Examination 1, except that the maximum achievable temperature of RTP was set to 1300° C.

As with the method in Examination 1, for each of the resulting annealed wafers, a defect density at a surface layer portion in a region from its surface to a depth of 5 μm, a BMD density of a bulk portion (a depth of 5 μm or more), and a slip length were respectively evaluated.

Table 2 shows experiment conditions and experiment results in Examination 2.

TABLE 2

| | | | Maximum | | | |
|---|---|---|---|---|---|---|
| | | | Achievable | Defect Density | BMD Density | |
| | Nitrogen | Oxygen | Temperature | of Surface | of | Slip |
| | Concentration | Concentration | of RTP | Layer Portion | Bulk Portion | Length |
| | (atoms/cm³) | (atoms/cm³) | (° C.) | (/cm²) | (/cm³) | (mm) |
| Comparative | 2.0 × 10¹⁴ | 0.8 × 10¹⁸ | 1300 | <1.0 | <1.0 × 10⁶ | 3 |
| Example 8 | | | | | | |
| Comparative | 2.0 × 10¹⁴ | 1.0 × 10¹⁸ | 1300 | <1.0 | 5.0 × 10⁶ | 2 |
| Example 9 | | | | | | |
| Comparative | 2.0 × 10¹⁴ | 1.2 × 10¹⁸ | 1300 | <1.0 | 1.0 × 10⁸ | 1 |
| Example 10 | | | | | | |
| Comparative | 2.0 × 10¹⁴ | 1.5 × 10¹⁸ | 1300 | <1.0 | 1.0 × 10⁸ | 1 |
| Example 11 | | | | | | |
| Comparative | 2.0 × 10¹⁴ | 1.8 × 10¹⁸ | 1300 | <1.0 | 2.2 × 10⁸ | 1 |
| Example 12 | | | | | | |
| Comparative | 2.8 × 10¹⁴ | 0.8 × 10¹⁸ | 1300 | <1.0 | 1.8 × 10⁷ | 2 |
| Example 13 | | | | | | |
| Example 9 | 2.8 × 10¹⁴ | 1.0 × 10¹⁸ | 1300 | <1.0 | 2.0 × 10⁹ | 0 |
| Example 10 | 2.8 × 10¹⁴ | 1.2 × 10¹⁸ | 1300 | <1.0 | 1.1 × 10⁹ | 1 |
| Example 11 | 2.8 × 10¹⁴ | 1.5 × 10¹⁸ | 1300 | <1.0 | 5.1 × 10⁹ | 0 |
| Example 12 | 2.8 × 10¹⁴ | 1.8 × 10¹⁸ | 1300 | <1.0 | 3.2 × 10⁹ | 1 |
| Comparative | 5.0 × 10¹⁴ | 0.8 × 10¹⁸ | 1300 | <1.0 | <1.0 × 10⁶ | 2 |
| Example 14 | | | | | | |
| Example 13 | 5.0 × 10¹⁴ | 1.0 × 10¹⁸ | 1300 | <1.0 | 1.1 × 10⁹ | 1 |
| Example 14 | 5.0 × 10¹⁴ | 1.2 × 10¹⁸ | 1300 | <1.0 | 4.9 × 10⁹ | 0 |
| Example 15 | 5.0 × 10¹⁴ | 1.5 × 10¹⁸ | 1300 | <1.0 | 6.5 × 10⁹ | 1 |
| Example 16 | 5.0 × 10¹⁴ | 1.8 × 10¹⁸ | 1300 | <1.0 | 5.1 × 10⁹ | 0 |

As shown in Table 2, even when the maximum achievable temperature of RTP is set to 1300° C., in the case where the nitrogen concentration is 2.0×10¹⁴ atoms/cm³ as in Examination 1, it is considered that BMD density is less than 1×10/cm³ even if the oxygen concentration is 1.8×10¹⁸ (Comparative Examples 8 to 12). In the case where the nitrogen concentration is 2.8×10¹⁴ atoms/cm³ or more, except for the case where the oxygen concentration is 0.8×10¹⁸ atoms/cm³ (Comparative Examples 13 and 14), it is considered that the BMD density is 1×10⁹/cm³ or more (Examples 9 to 16). Further, it is considered that the defect density of the surface layer portion is less than 1.0/cm² in each condition and the slip length is short, causing no problem.

### [Examination 3]

The annealed wafer was produced for each condition by the same method as in Examination 1, except that the maximum achievable temperature of RTP was set to 1350° C.

As with the method in Examination 1, for each of the resulting annealed wafers, a defect density at a surface layer portion in a region from its surface to a depth of 5 μm, a BMD density of a bulk portion (a depth of 5 μm or more), and a slip length were respectively evaluated.

Table 3 shows experiment conditions and experiment results in Examination 3.

TABLE 3

| | | | Maximum | | | |
|---|---|---|---|---|---|---|
| | | | Achievable | Defect Density | BMD Density | |
| | Nitrogen | Oxygen | Temperature | of Surface | of | Slip |
| | Concentration | Concentration | of RTP | Layer Portion | Bulk Portion | Length |
| | (atoms/cm³) | (atoms/cm³) | (° C.) | (/cm²) | (/cm³) | (mm) |
| Comparative | 2.0 × 10¹⁴ | 0.8 × 10¹⁸ | 1350 | <1.0 | <1.0 × 10⁶ | 3 |
| Example 15 | | | | | | |
| Comparative | 2.0 × 10¹⁴ | 1.0 × 10¹⁸ | 1350 | <1.0 | <1.0 × 10⁶ | 3 |
| Example 16 | | | | | | |
| Comparative | 2.0 × 10¹⁴ | 1.2 × 10¹⁸ | 1350 | <1.0 | 4.8 × 10⁷ | 2 |
| Example 17 | | | | | | |
| Comparative | 2.0 × 10¹⁴ | 1.5 × 10¹⁸ | 1350 | <1.0 | 4.0 × 10⁷ | 1 |
| Example 18 | | | | | | |
| Comparative | 2.0 × 10¹⁴ | 1.8 × 10¹⁸ | 1350 | <1.0 | 8.2 × 10⁸ | 1 |
| Example 19 | | | | | | |
| Comparative | 2.8 × 10¹⁴ | 0.8 × 10¹⁸ | 1350 | <1.0 | 6.3 × 10⁶ | 3 |
| Example 20 | | | | | | |
| Example 17 | 2.8 × 10¹⁴ | 1.0 × 10¹⁸ | 1350 | <1.0 | 1.0 × 10⁹ | 1 |
| Example 18 | 2.8 × 10¹⁴ | 1.2 × 10¹⁸ | 1350 | <1.0 | 1.0 × 10⁹ | 2 |
| Example 19 | 2.8 × 10¹⁴ | 1.5 × 10¹⁸ | 1350 | <1.0 | 1.6 × 10⁹ | 1 |
| Example 20 | 2.8 × 10¹⁴ | 1.8 × 10¹⁸ | 1350 | <1.0 | 2.5 × 10⁹ | 1 |
| Comparative | 5.0 × 10¹⁴ | 0.8 × 10¹⁸ | 1350 | <1.0 | <1.0 × 10⁶ | 4 |
| Example 21 | | | | | | |
| Example 21 | 5.0 × 10¹⁴ | 1.0 × 10¹⁸ | 1350 | <1.0 | 2.0 × 10⁹ | 1 |
| Example 22 | 5.0 × 10¹⁴ | 1.2 × 10¹⁸ | 1350 | <1.0 | 5.8 × 10⁹ | 0 |
| Example 23 | 5.0 × 10¹⁴ | 1.5 × 10¹⁸ | 1350 | <1.0 | 5.0 × 10⁹ | 1 |
| Example 24 | 5.0 × 10¹⁴ | 1.8 × 10¹⁸ | 1350 | <1.0 | 2.7 × 10⁹ | 1 |

As shown in Table 3, even when the maximum achievable temperature of RTP is set to 1350° C., in the case where the nitrogen concentration is 2.0×10¹⁴ atoms/cm³ as in Examination 1, it is considered that BMD density is less than 1×10⁹/cm³ even if the oxygen concentration is 1.8×10¹⁸ atoms/cm³ (Comparative Examples 15 to 19). In the case where the nitrogen concentration is 2.8×10¹⁴ atoms/cm³ or more, except for the case where the oxygen concentration is 0.8×10¹⁸ atoms/cm³ (Comparative Examples 20 and 21), it is considered that the BMD density is 1×10⁹/cm³ or more (Examples 17 to 24). Further, it is considered that the defect density of the surface layer portion is less than 1.0/cm² in each condition and the slip length is short, causing no problem.

In addition, from the results in Tables 1-3, it is generally considered that the higher the maximum achievable temperature in RIP, the more likely the BMD density decreases. It is thought that the higher the heat treatment temperature, the more likely the precipitate nucleus of BMD increased when growing the silicon single crystal is to disappear due to RTP. More preferably, the maximum achievable temperature in the above-mentioned RTP is from 1250° C. to 1300° C. in terms of increasing the BMD density.

### [Examination 4]

Each of the double-side polished silicon wafers obtained under the conditions similar to those in Examination 1, the wafers having different nitrogen concentrations and different oxygen concentrations and having a diameter of 300 mm and a thickness of 750 μm, was placed in the reaction tube kept at 400° C. using the well-known RTP apparatus. Then, the first temperature T1 (maximum achievable temperature in first RTP) was set to 1250° C., and the first RTP and second RTP were performed according to the thermal process sequence as shown in FIG. 2.

The particular manufacture conditions of others in the first RTP and second RTP are as follows:

(a) first RTP
inactive gas atmosphere: 100% argon gas
temperature ramp up rate ΔTu1: 10° C./second
holding time t1 of first temperature T1: 30 seconds
temperature ramp down rate ΔTd1: 50° C./second
second temperature T2: 800° C.

holding time t2 of second temperature T2: 15 seconds

(b) second RTP
oxidizing gas atmosphere: 100% oxygen gas
holding time t3 of second temperature T2: 15 seconds
temperature ramp up rate ΔTu2: 10° C./second
third temperature T3: 1250° C.
holding time t4 of third temperature T3: 30 seconds
temperature ramp down rate ΔTd2: 50° C./second

For each of the resulting annealed wafers, a defect density at a surface layer portion in a region from its surface to a depth of 5 μm, a BMD density of a bulk portion (a depth of 5 μm or more), and the maximum slip length were respectively evaluated.

Further, for each of the resulting annealed wafers, an oxygen concentration profile in a region from its surface to a depth of 5 μm was measured by a secondary ion mass spectroscope (SIMS; manufactured by CAMECA SAS, Ims-6f), to evaluate the minimum oxygen concentration in this oxygen concentration profile.

Table 4 shows experiment conditions and experiment results in Examination 4.

TABLE 4

| | | | Maximum | | | |
|---|---|---|---|---|---|---|
| | | | Achievable | Defect Density | BMD Density | |
| | Nitrogen | Oxygen | Temperature | of Surface | of | Slip |
| | Concentration | Concentration | of First RTP | Layer Portion | Bulk Portion | Length |
| | (atoms/cm³) | (atoms/cm³) | (° C.) | (/cm²) | (/cm³) | (mm) |
| Comparative | 2.0 × 10¹⁴ | 0.8 × 10¹⁸ | 1250 | <1.0 | 0.8 × 10⁷ | 2 |
| Example 22 | | | | | | |
| Comparative | 2.0 × 10¹⁴ | 1.0 × 10¹⁸ | 1250 | <1.0 | 2.8 × 10⁷ | 1 |
| Example 23 | | | | | | |
| Comparative | 2.0 × 10¹⁴ | 1.2 × 10¹⁸ | 1250 | <1.0 | 1.0 × 10⁸ | 2 |
| Example 24 | | | | | | |
| Comparative | 2.0 × 10¹⁴ | 1.5 × 10¹⁸ | 1250 | <1.0 | 4.8 × 10⁸ | 1 |
| Example 25 | | | | | | |
| Comparative | 2.0 × 10¹⁴ | 1.8 × 10¹⁸ | 1250 | <1.0 | 5.5 × 10⁸ | 0 |
| Example 26 | | | | | | |
| Comparative | 2.8 × 10¹⁴ | 0.8 × 10¹⁸ | 1250 | <1.0 | 8.8 × 10⁷ | 1 |
| Example 27 | | | | | | |
| Example 25 | 2.8 × 10¹⁴ | 1.0 × 10¹⁸ | 1250 | <1.0 | 1.0 × 10⁹ | 1 |
| Example 26 | 2.8 × 10¹⁴ | 1.2 × 10¹⁸ | 1250 | <1.0 | 1.3 × 10⁹ | 1 |
| Example 27 | 2.8 × 10¹⁴ | 1.5 × 10¹⁸ | 1250 | <1.0 | 4.0 × 10⁹ | 1 |
| Example 28 | 2.8 × 10¹⁴ | 1.8 × 10¹⁸ | 1250 | <1.0 | 6.2 × 10⁹ | 0 |
| Comparative | 5.0 × 10¹⁴ | 0.8 × 10¹⁸ | 1250 | <1.0 | 6.5 × 10⁷ | 1 |
| Example 28 | | | | | | |
| Example 29 | 5.0 × 10¹⁴ | 1.0 × 10¹⁸ | 1250 | <1.0 | 3.4 × 10⁹ | 1 |
| Example 30 | 5.0 × 10¹⁴ | 1.2 × 10¹⁸ | 1250 | <1.0 | 5.7 × 10⁹ | 0 |
| Example 31 | 5.0 × 10¹⁴ | 1.5 × 10¹⁸ | 1250 | <1.0 | 5.5 × 10⁹ | 1 |
| Example 32 | 5.0 × 10¹⁴ | 1.8 × 10¹⁸ | 1250 | <1.0 | 6.1 × 10⁹ | 0 |

As shown in Table 4, it is considered that there is a tendency for the BMD density of the bulk portion not to increase but rather to decrease as compared with Table 1, if RTP (first RTP) in the inert gas atmosphere is performed before RTP (second RTP) in the oxidizing gas atmosphere. It is thought that since the heat treatment temperature in the first RTP is as high as 1250° C. or higher, the precipitate nucleus of BMD generated when growing the silicon single crystal disappears in the above-mentioned first RTP. However, even if this is the case, it is considered that the BMD density is 1×10⁹/cm³ or more in Examples 25-32.

Further, the minimum oxygen concentration in the oxygen concentration profile in the depth direction from the surface of the obtained annealed wafer to a depth of 5 μm is greater than the oxygen concentration when growing the silicon single crystal in any condition, and the decrease in the oxygen concentration of the surface layer portion of the wafer is not observed.

What is claimed is:

1. A method for manufacturing a silicon wafer, the method comprising the steps of:
growing a silicon single crystal having an oxygen concentration of from 1.0×10¹⁸ to 1.8×10¹⁸ atoms/cm³ and a nitrogen concentration of 2.8×10¹⁴ to 5.0×10¹⁵ atoms/cm³ by the Czochralski method in which nitrogen is added to a silicon melt in an inert gas atmosphere to which hydrogen gas is added, by controlling V/G (where V indicates a pull rate and G indicates a temperature gradient in the direction of a raising axis of the silicon single crystal) so as to form a region where a vacancy-type point defect exists;
slicing a silicon wafer from said grown silicon single crystal, the silicon wafer then being subjected to a planarization process and a mirror polish process; and
subjecting said mirror polished silicon wafer to a rapid thermal process in an oxidizing gas atmosphere at a maximum achievable temperature from 1250° C. to 1380° C. for 1 second to 60 seconds.

2. A method for manufacturing a silicon wafer, the method comprising the steps of:
growing a silicon single crystal having an oxygen concentration of from 1.0×10¹⁸ to 1.8×10¹⁸ atoms/cm³ and a nitrogen concentration of 2.8×10¹⁴ to 5.0×10¹⁵ atoms/cm³ by the Czochralski method in which nitrogen is added to a silicon melt in an inert gas atmosphere to which hydrogen gas is added, by controlling V/G (where V indicates a pull rate and G indicates a temperature gradient in the direction of a raising axis of the silicon single crystal) so as to form a region where a vacancy-type point defect exists;
slicing a silicon wafer from said grown silicon single crystal, the silicon wafer then being subjected to a planarization process and a mirror polish process;
subjecting said mirror polished silicon wafer to a first rapid thermal process in an inert gas atmosphere at a maximum achievable temperature from 1250° C. to 1380° C. for 1 second to 60 seconds; and
after said first rapid thermal process, subjecting said silicon wafer to a second rapid thermal process in an oxidizing gas atmosphere at a maximum achievable temperature from 1250° C. to 1380° C. for 1 second to 60 seconds.

3. A method for manufacturing a silicon wafer as claimed in claim 1, wherein a partial pressure of hydrogen gas contained in said inert gas atmosphere to which hydrogen gas is added is 3% or less.

4. A method for manufacturing a silicon wafer as claimed in claim 2, wherein a partial pressure of hydrogen gas contained in said inert gas atmosphere to which hydrogen gas is added is 3% or less.
